(19) United States
(12) Patent Application Publication
(10) Pub. No.: US 2019/0032192 A1
(43) Pub. Date: Jan. 31, 2019

(54) METALLIC STENCIL AND EVAPORATION MASK DEVICE

(71) Applicant: WUHAN CHINA STAR OPTOELECTRONICS SEMICONDUCTOR DISPLAY TECHNOLOGY CO., LTD., Wuhan (CN)

(72) Inventor: Peng ZHANG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 15/576,856

(22) PCT Filed: Oct. 17, 2017
(86) PCT No.: PCT/CN2017/106506

§ 371 Date: Nov. 27, 2017

(30) Foreign Application Priority Data
Jul. 25, 2017 (CN) 201710614380.1

(51) Int. Cl. C23C 14/04; C23C 14/24

(52) U.S. Cl. CPC C23C 14/042; H01L 51/0011; C23C 14/24

(57) ABSTRACT

The present disclosure provides a metallic stencil, comprising: a first region including an array of a plurality of first perforations on a surface of the metallic stencil; a second region including an array of a plurality of second perforations, wherein the second perforations surround the first region; and a third region including an array of a plurality of third perforations, wherein the third perforations surround the second region.

### FIELD OF THE DISCLOSURE

The present disclosure relates to the field of techniques of manufacturing display panel, and more particularly to a metallic stencil and an evaporation mask device.

### BACKGROUND

Organic light emitting display (OLED) possesses many outstanding properties, including self-illumination, low power consumption, short response time, high contrast, and large viewing angle. To manufacture OLED, it is required to execute evaporation for R, G, and B pixels, and mask plates are used to shield non-evaporation area during evaporation.

With development of displays, resolution of display products is increased, and metallic mask plates have to be precisely produced to meet the requirement. Before the metallic stencils are welded to the frame, it is needed to stretch the metallic stencils to make them flat using stencil stretching apparatus. However, during stretching process, the metallic stencils are liable to be wrinkled. This would lead to deformation of perforations on surface of the metallic stencils, causing low aligning accuracy between perforations and pixels, and ultimately influencing evaporation accuracy.

Therefore, according to the metallic mask device used in the prior art, the metallic stencils are liable to be wrinkled during stretching process, which would lead to deformation of perforations on surface of the metallic stencils, cause low aligning accuracy between perforations and pixels, and ultimately influence evaporation accuracy.

### SUMMARY OF THE DISCLOSURE

The present disclosure provides a metallic stencil includes two deformation absorbing areas, and the deformed portions of the metallic stencil that correspond to the display area can be moved to the deformation absorbing areas, so as to solve the problems arising in the conventional metallic mask device, where the metallic stencil is liable to be wrinkled during stretching process which would lead to deformation of perforations on surface of the metallic stencil, cause low aligning accuracy between perforations and pixels, and ultimately influence evaporation accuracy.

To solve the above mentioned problems, the present disclosure provides the following technical schemes.

The present disclosure provides a metallic stencil configured as a mask plate for a substrate in a vacuum deposition process, a surface of the metallic stencil comprising:

a first region including an array of a plurality of first perforations, wherein the first region corresponds to a display area of a display panel, and the first perforations are configured for deposition of a deposition material onto corresponding locations on the substrate;

a second region including an array of a plurality of second perforations, wherein the second perforations correspond to a non-display area of the display panel and surround the first region, and the second region is configured as a first deformation absorbing area of the metallic stencil when the metallic stencil is stretched; and

a third region including an array of a plurality of third perforations, wherein the third perforations surround the second region, and the third region is configured as a second deformation absorbing area of the metallic stencil when the metallic stencil is stretched;

wherein the first perforations, the second perforations, and the third perforations are of the same shape and size.

According to a preferred embodiment of the present disclosure, rows of the third perforations in the third region are two to three times rows of the second perforations in the second region; and columns of the third perforations in the third region are two to three times columns of the second perforations in the second region.

According to a preferred embodiment of the present disclosure, an interval between adjacent rows of the first perforations in the first region, an interval between adjacent rows of the second perforations in the second region, and an interval between adjacent rows of the third perforations in the third region are the same; and an interval between adjacent columns of the first perforations in the first region, an interval between adjacent columns of the second perforations in the second region, and an interval between adjacent columns of the third perforations in the third region are the same.

According to a preferred embodiment of the present disclosure, an interval between a row of the first perforations at a periphery of the first region and an adjacent row of the second perforations at a periphery of the second region is identical to the interval between adjacent rows of the first perforations in the first region and identical to the interval between adjacent rows of the second perforations in the second region; and an interval between a column of the first perforations at the periphery of the first region and an adjacent column of the second perforations at the periphery of the second region is identical to the interval between adjacent columns of the first perforations in the first region and identical to the interval between adjacent columns of the second perforations in the second region; and an interval between a row of the third perforations at a periphery of the third region and an adjacent row of the second perforations at the periphery of the second region is identical to the interval between adjacent rows of the third perforations in the third region and identical to the interval between adjacent rows of the second perforations in the second region; and an interval between a column of the third perforations at the periphery of the third region and an adjacent column of the second perforations at the periphery of the second region is identical to the interval between adjacent columns of the third perforations in the third region and identical to the interval between adjacent columns of the second perforations in the second region.

The present disclosure further provides a metallic stencil configured as a mask plate for a substrate in a vacuum deposition process, a surface of the metallic stencil comprising:

a first region including an array of a plurality of first perforations, wherein the first region corresponds to a display area of a display panel, and the first perforations are configured for deposition of a deposition material onto corresponding locations on the substrate;

a second region including an array of a plurality of second perforations, wherein the second perforations correspond to a non-display area of the display panel and surround the first region, and the second region is configured as a first deformation absorbing area of the metallic stencil when the metallic stencil is stretched; and

a third region including an array of a plurality of third perforations, wherein the third perforations surround the second region, and the third region is configured as a second deformation absorbing area of the metallic stencil when the metallic stencil is stretched.

According to a preferred embodiment of the present disclosure, rows of the third perforations in the third region are two to three times rows of the second perforations in the second region; and columns of the third perforations in the third region are two to three times columns of the second perforations in the second region.

According to a preferred embodiment of the present disclosure, an interval between adjacent rows of the first perforations in the first region, an interval between adjacent rows of the second perforations in the second region, and an interval between adjacent rows of the third perforations in the third region are the same; and an interval between adjacent columns of the first perforations in the first region, an interval between adjacent columns of the second perforations in the second region, and an interval between adjacent columns of the third perforations in the third region are the same.

According to a preferred embodiment of the present disclosure, an interval between a row of the first perforations at a periphery of the first region and an adjacent row of the second perforations at a periphery of the second region is identical to the interval between adjacent rows of the first perforations in the first region and identical to the interval between adjacent rows of the second perforations in the second region; and an interval between a column of the first perforations at the periphery of the first region and an adjacent column of the second perforations at the periphery of the second region is identical to the interval between adjacent columns of the first perforations in the first region and identical to the interval between adjacent columns of the second perforations in the second region; and an interval between a row of the third perforations at a periphery of the third region and an adjacent row of the second perforations at the periphery of the second region is identical to the interval between adjacent rows of the third perforations in the third region and identical to the interval between adjacent rows of the second perforations in the second region; and an interval between a column of the third perforations at the periphery of the third region and an adjacent column of the second perforations at the periphery of the second region is identical to the interval between adjacent columns of the third perforations in the third region and identical to the interval between adjacent columns of the second perforations in the second region.

In accordance with the above mentioned objective of the present disclosure, the present disclosure provides an evaporation mask device, comprising:

a frame;

a metallic stencil disposed inside the frame, wherein the metallic stencil includes a plurality of deposition perforations on a surface of the metallic stencil, and the metallic stencil is configured as a mask plate for a substrate in a vacuum deposition process;

a supporting bar disposed on a bottom of the metallic stencil for preventing a central portion of the metallic stencil from sagging; and

a shielding plate disposed on a bottom of the supporting bar and including a screen section and a planar section disposed outside of the screen section, wherein the screen section corresponds to the deposition perforations on the surface of the metallic stencil, and the shielding plate is used for preventing a material entering the deposition perforations from diffusing to outer regions;

wherein a surface of the metallic stencil comprises:

a first region including an array of a plurality of first perforations, wherein the first region corresponds to a display area of a display panel, and the first perforations are configured for deposition of a deposition material onto corresponding locations on the substrate;

a second region including an array of a plurality of second perforations, wherein the second perforations correspond to a non-display area of the display panel and surround the first region, and the second region is configured as a first deformation absorbing area of the metallic stencil when the metallic stencil is stretched; and

a third region including an array of a plurality of third perforations, wherein the third perforations surround the second region, and the third region is configured as a second deformation absorbing area of the metallic stencil when the metallic stencil is stretched;

wherein the planar section of the shielding plate is disposed below the second region and the third region.

According to a preferred embodiment of the present disclosure, the first perforations, the second perforations, and the third perforations are of the same shape and size.

According to a preferred embodiment of the present disclosure, rows of the third perforations in the third region are two to three times rows of the second perforations in the second region; and wherein columns of the third perforations in the third region are two to three times columns of the second perforations in the second region.

According to a preferred embodiment of the present disclosure, an interval between adjacent rows of the first perforations in the first region, an interval between adjacent rows of the second perforations in the second region, and an interval between adjacent rows of the third perforations in the third region are the same; and an interval between adjacent columns of the first perforations in the first region, an interval between adjacent columns of the second perforations in the second region, and an interval between adjacent columns of the third perforations in the third region are the same.

According to a preferred embodiment of the present disclosure, an interval between a row of the first perforations at a periphery of the first region and an adjacent row of the second perforations at a periphery of the second region is identical to the interval between adjacent rows of the first perforations in the first region and identical to the interval between adjacent rows of the second perforations in the second region; and an interval between a column of the first perforations at the periphery of the first region and an adjacent column of the second perforations at the periphery of the second region is identical to the interval between adjacent columns of the first perforations in the first region and identical to the interval between adjacent columns of the second perforations in the second region; and an interval between a row of the third perforations at a periphery of the third region and an adjacent row of the second perforations at the periphery of the second region is identical to the interval between adjacent rows of the third perforations in the third region and identical to the interval between adjacent rows of the second perforations in the second region; and an interval between a column of the third perforations at the periphery of the third region and an adjacent column of the second perforations at the periphery of the second region is identical to the interval between adjacent columns of the third perforations in the third region and identical to the interval between adjacent columns of the second perforations in the second region.

Compared to the metallic stencil conventionally used for the evaporation mask device, the metallic stencil of the present disclosure includes deformation absorbing areas. According to the subject invention, the stretching process of the metallic stencil is tuned constantly during stretching of the metallic stencil, and the wrinkles in the regions of the metallic stencil that correspond to the display area are moved to the deformation absorbing areas. Therefore, the subject invention ensures aligning accuracy between the metallic stencil and the pixels, increasing evaporation accuracy. The subject invention solves the problems arising in the conventional evaporation mask device, where the metallic stencil of the conventional evaporation mask device is liable to be wrinkled during stretching process which would lead to deformation of perforations on surface of the metallic stencil, cause low aligning accuracy between perforations and pixels, and ultimately influence evaporation accuracy.

### BRIEF DESCRIPTION OF THE DRAWINGS

To detailedly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is a schematic diagram showing a structure of a metallic stencil according to the present disclosure.

FIG. 2 is a schematic diagram showing a structure of an evaporation mask device according to the present disclosure.

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, the same reference symbol represents the same or similar components.

According to the metallic mask device used in the prior art, the metallic stencils are liable to be wrinkled during stretching process, which would lead to deformation of perforations on surface of the metallic stencils, cause low aligning accuracy between perforations and pixels, and ultimately influence evaporation accuracy.

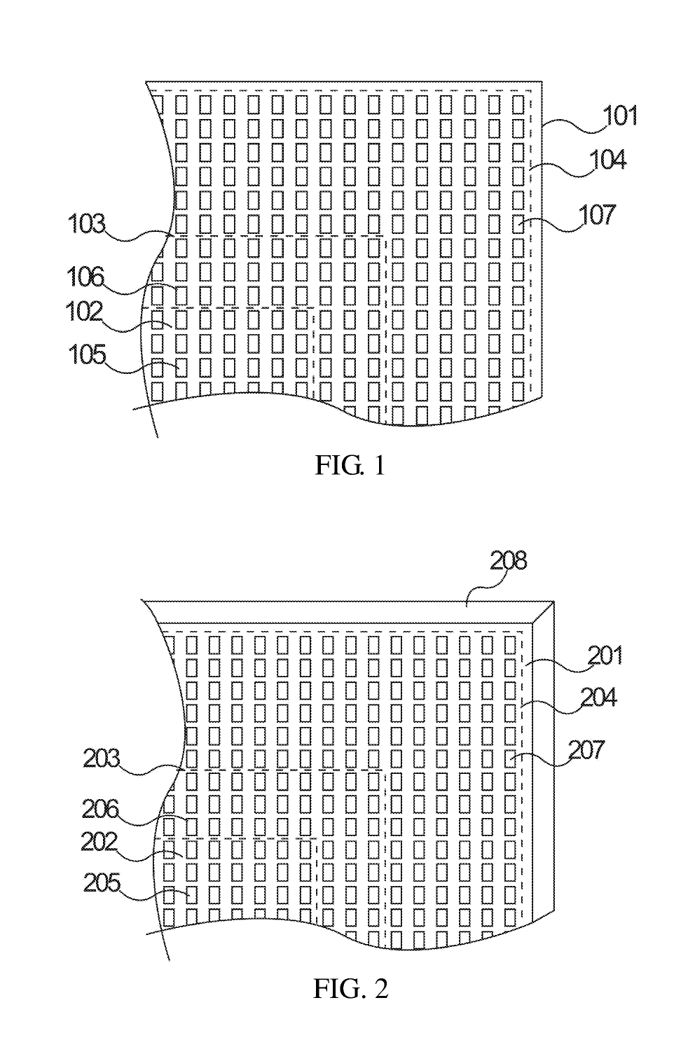

As shown in FIG. 1, the present disclosure provides a metallic stencil 101 configured as a mask plate for a substrate in a vacuum deposition process. The metallic stencil 101 comprises a first region 102 on a surface of the metallic stencil 101, a second region 103 surrounding the first region 102, and a third region 104 surrounding the second region 103.

The first region 102 of the metallic stencil 101 includes an array of a plurality of first perforations 105. The first region 102 corresponds to a display area of a display panel. The first perforations 105 are configured to be accurately aligned with sub-pixels for displaying on surface of the substrate, such that a deposition material passes through the first perforations 105 and is deposited onto corresponding pixel region on the substrate.

The second region 103 of the metallic stencil 101 includes an array of a plurality of second perforations 106. The second perforations 106 correspond to a non-display area of the display panel. The second region 103 surrounds the first region 102. The second region 103 is configured as a first deformation absorbing area of the metallic stencil 101 during a stencil stretching process of the metallic stencil.

The third region 104 of the metallic stencil 101 includes an array of a plurality of third perforations 107. The third perforations 107 surround the second region 103. The third region 104 is configured as a second deformation absorbing area of the metallic stencil 101 during the stencil stretching process of the metallic stencil.

Since the metallic stencil 101 is thin in thickness and is flexible, a central portion of the metallic stencil 101 will sag due to gravity. Sagging makes the perforations on the surface of the metallic stencil 101 deform, and results in low aligning accuracy between the perforations and pixels. Therefore, the metallic stencil 101 has to be tensioned and flattened by the stencil stretching process before the metallic stencil 101 is welded to the frame. Once the metallic stencil 101 is flattened, the metallic stencil 101 is welded to the frame to form a mask device.

However, during stretching process of the metallic stencil 101 by using the stencil stretching apparatus, the metallic stencil 101 are liable to be wrinkled. The metallic stencil 101 cannot be flattened at a time. During stretching process, the stretched portion, the stretching direction, and the stretching force have to adjusted constantly all the way through the stretching process to ensure that the area of the metallic stencil 101 corresponding to the display area is flattened, and the metallic stencil 101 has correct shaped perforations.

According to the present disclosure, in stretching process of the metallic stencil 101, the first region 102 of the metallic stencil 101 is stretched first. By tuning the stretching process, the wrinkles in the first region 102 are moved into the second region 103. The perforations in the second region 103 will deform to absorb the wrinkles coming from the first region 102. If there are too many wrinkles existing in the second region 103, it is required to further tune the stretching process in order to move the wrinkles in the second region 103 into the third region 104. The perforations in the third region 104 will deform to absorb the wrinkles coming from the second region 103. As such, a flattened first region 102, and a relatively flat second region 103 and third region 104 are formed. The perforations in the second region 103 and the third region 104 are not used for depositing the material, but used for absorbing surface non-flatness solely.

The first perforations 105, the second perforations 106, and the third perforations 107 are of the same shape and size. Thus, while forming perforations of the metallic stencil 101, the first perforations 105, the second perforations 106, and the third perforations 107 can be formed through only one photomask. Not only can the manufacturing process be simplified but also deformation absorbing ability of the metallic stencil is achieved at the same time.

Rows of the third perforations in the third region 104 are two to three times rows of the second perforations in the second region 103. Columns of the third perforations in the third region 104 are two to three times columns of the second perforations in the second region 103. By expanding area of the third region 104, deformation absorbing amount can be increased. The third region 104 is adjacent to edge of the metallic stencil 101, and is far away from the first region 102, therefore the third region 104 has no influence on flatness of the first region 102.

An interval between adjacent rows of the first perforations in the first region 102, an interval between adjacent rows of the second perforations in the second region 103, and an interval between adjacent rows of the third perforations in the third region 104 are the same. An interval between adjacent columns of the first perforations in the first region 102, an interval between adjacent columns of the second perforations in the second region 103, and an interval between adjacent columns of the third perforations in the third region 104 are the same. All the regions have the same interval between adjacent rows or adjacent columns of perforations to ensure continuity of wrinkle movement.

An interval between a row of the first perforations at a periphery of the first region 102 and an adjacent row of the second perforations at a periphery of the second region 103 is identical to the interval between adjacent rows of the first perforations in the first region 102 and identical to the interval between adjacent rows of the second perforations in the second region 103. An interval between a column of the first perforations at the periphery of the first region 102 and an adjacent column of the second perforations at the periphery of the second region 103 is identical to the interval between adjacent columns of the first perforations in the first region 102 and identical to the interval between adjacent columns of the second perforations in the second region 103. An interval between a row of the third perforations at a periphery of the third region 104 and an adjacent row of the second perforations at the periphery of the second region 103 is identical to the interval between adjacent rows of the third perforations in the third region 104 and identical to the interval between adjacent rows of the second perforations in the second region 103. An interval between a column of the third perforations at the periphery of the third region 104 and an adjacent column of the second perforations at the periphery of the second region 103 is identical to the interval between adjacent columns of the third perforations in the third region 104 and identical to the interval between adjacent columns of the second perforations in the second region 103. The interval between adjacent regions is identical to the interval between adjacent rows or adjacent columns of the perforations in each region, in order to ensure continuity of wrinkle movement between regions.

As shown in FIG. 2, the present disclosure also provides an evaporation mask device. The evaporation mask device comprises:
a frame 208;
a metallic stencil 201 disposed inside the frame 208, wherein the metallic stencil 201 includes a plurality of deposition perforations on a surface of the metallic stencil 201, and the metallic stencil 201 is configured as a mask plate for a substrate in a vacuum deposition process;
a supporting bar disposed on a bottom of the metallic stencil 201 to prevent a central portion of the metallic stencil from sagging; and
a shielding plate disposed on a bottom of the supporting bar and including a screen section and a planar section disposed outside of the screen section, wherein the screen section corresponds to the deposition perforations on the surface of the metallic stencil 201, and the shielding plate prevents a material entering the deposition perforations from diffusing to outer regions.

A surface of the metallic stencil 201 comprises:
a first region 202 including an array of a plurality of first perforations 205, wherein the first region 202 corresponds to a display area of a display panel, and the first perforations 205 are configured to deposit a deposition material onto corresponding locations on the substrate;
a second region 203 including an array of a plurality of second perforations 206, wherein the second perforations 206 correspond to a non-display area of the display panel and surround the first region 202, and the second region 203 is configured as a first deformation absorbing area of the metallic stencil during a stencil stretching process of the metallic stencil; and
a third region 204 including an array of a plurality of third perforations 207, wherein the third perforations 207 surround the second region 203, and the third region 204 is configured as a second deformation absorbing area of the metallic stencil during the stencil stretching process of the metallic stencil.

The planar section of the shielding plate is disposed below the second region 203 and the third region 204.

The perforations on surface of the second region 203 and the third region 204 are used for absorbing wrinkles, rather than depositing the evaporation material. Additionally, to avoid the evaporation material passing through the perforations on surface of the second region 203 and the third region 204 and being deposited on surface of the substrate, the planar section of the shielding plater is disposed correspondingly to the second region 203 and the third region 204, in order to block the perforations on surface of the second region 203 and the third region 204 and thus prevent the evaporation material from entering the perforations on surface of the second region 203 and the third region 204.

The metallic stencil of the evaporation mask device according to this preferred embodiment operates based on the same principle as the metallic stencil 201 described in the previous preferred embodiment, therefore the operation principle thereof can be understood by referring to the previous preferred embodiment and is omitted.

Compared to the metallic stencil conventionally used for the evaporation mask device, the metallic stencil of the present disclosure includes deformation absorbing areas. According to the subject invention, the stretching process of the metallic stencil is tuned constantly during stretching of the metallic stencil, and the wrinkles in the regions of the metallic stencil that correspond to the display area are moved to the deformation absorbing areas. Therefore, the subject invention ensures aligning accuracy between the metallic stencil and the pixels, increasing evaporation accuracy. The subject invention solves the problems arising in the conventional evaporation mask device, where the metallic stencil of the conventional evaporation mask device is liable to be wrinkled during stretching process which would lead to deformation of perforations on surface of the metallic stencil, cause low aligning accuracy between perforations and pixels, and ultimately influence evaporation accuracy.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A metallic stencil configured as a mask plate for a substrate in a vacuum deposition process, a surface of the metallic stencil comprising:
a first region including an array of a plurality of first perforations, wherein the first region corresponds to a display area of a display panel, and the first perforations are configured for deposition of a deposition material onto corresponding locations on the substrate;
a second region including an array of a plurality of second perforations, wherein the second perforations correspond to a non-display area of the display panel and surround the first region, and the second region is configured as a first deformation absorbing area of the metallic stencil when the metallic stencil is stretched; and
a third region including an array of a plurality of third perforations, wherein the third perforations surround the second region, and the third region is configured as a second deformation absorbing area of the metallic stencil when the metallic stencil is stretched;
wherein the first perforations, the second perforations, and the third perforations are of the same shape and size.

2. The metallic stencil according to claim 1, wherein rows of the third perforations in the third region are two to three times rows of the second perforations in the second region; and wherein columns of the third perforations in the third region are two to three times columns of the second perforations in the second region.

3. The metallic stencil according to claim 2, wherein an interval between adjacent rows of the first perforations in the first region, an interval between adjacent rows of the second perforations in the second region, and an interval between adjacent rows of the third perforations in the third region are the same; and wherein an interval between adjacent columns of the first perforations in the first region, an interval between adjacent columns of the second perforations in the second region, and an interval between adjacent columns of the third perforations in the third region are the same.

4. The metallic stencil according to claim 3, wherein an interval between a row of the first perforations at a periphery of the first region and an adjacent row of the second perforations at a periphery of the second region is identical to the interval between adjacent rows of the first perforations in the first region and identical to the interval between adjacent rows of the second perforations in the second region; and an interval between a column of the first perforations at the periphery of the first region and an adjacent column of the second perforations at the periphery of the second region is identical to the interval between adjacent columns of the first perforations in the first region and identical to the interval between adjacent columns of the second perforations in the second region; and wherein an interval between a row of the third perforations at a periphery of the third region and an adjacent row of the second perforations at the periphery of the second region is identical to the interval between adjacent rows of the third perforations in the third region and identical to the interval between adjacent rows of the second perforations in the second region; and an interval between a column of the third perforations at the periphery of the third region and an adjacent column of the second perforations at the periphery of the second region is identical to the interval between adjacent columns of the third perforations in the third region and identical to the interval between adjacent columns of the second perforations in the second region.

5. A metallic stencil configured as a mask plate for a substrate in a vacuum deposition process, a surface of the metallic stencil comprising:
a first region including an array of a plurality of first perforations, wherein the first region corresponds to a display area of a display panel, and the first perforations are configured for deposition of a deposition material onto corresponding locations on the substrate;
a second region including an array of a plurality of second perforations, wherein the second perforations correspond to a non-display area of the display panel and surround the first region, and the second region is configured as a first deformation absorbing area of the metallic stencil when the metallic stencil is stretched; and
a third region including an array of a plurality of third perforations, wherein the third perforations surround the second region, and the third region is configured as a second deformation absorbing area of the metallic stencil when the metallic stencil is stretched.

6. The metallic stencil according to claim 5, wherein rows of the third perforations in the third region are two to three times rows of the second perforations in the second region; and wherein columns of the third perforations in the third region are two to three times columns of the second perforations in the second region.

7. The metallic stencil according to claim 6, wherein an interval between adjacent rows of the first perforations in the first region, an interval between adjacent rows of the second perforations in the second region, and an interval between adjacent rows of the third perforations in the third region are the same; and wherein an interval between adjacent columns of the first perforations in the first region, an interval between adjacent columns of the second perforations in the second region, and an interval between adjacent columns of the third perforations in the third region are the same.

8. The metallic stencil according to claim 7, wherein an interval between a row of the first perforations at a periphery of the first region and an adjacent row of the second perforations at a periphery of the second region is identical to the interval between adjacent rows of the first perforations in the first region and identical to the interval between adjacent rows of the second perforations in the second region; and an interval between a column of the first perforations at the periphery of the first region and an adjacent column of the second perforations at the periphery of the second region is identical to the interval between adjacent columns of the first perforations in the first region and identical to the interval between adjacent columns of the second perforations in the second region; and wherein an interval between a row of the third perforations at a periphery of the third region and an adjacent row of the second perforations at the periphery of the second region is identical to the interval between adjacent rows of the third perforations in the third region and identical to the interval between adjacent rows of the second perforations in the second region; and an interval between a column of the third perforations at the periphery of the third region and an adjacent column of the second perforations at the periphery of the second region is identical to the interval between adjacent columns of the third perforations in the third region and identical to the interval between adjacent columns of the second perforations in the second region.

9. An evaporation mask device, comprising:
a frame;
a metallic stencil disposed inside the frame, wherein the metallic stencil includes a plurality of deposition perforations on a surface of the metallic stencil, and the metallic stencil is configured as a mask plate for a substrate in a vacuum deposition process;
a supporting bar disposed on a bottom of the metallic stencil for preventing a central portion of the metallic stencil from sagging; and
a shielding plate disposed on a bottom of the supporting bar and including a screen section and a planar section disposed outside of the screen section, wherein the screen section corresponds to the deposition perforations on the surface of the metallic stencil, and the shielding plate is used for preventing a material entering the deposition perforations from diffusing to outer regions;
wherein a surface of the metallic stencil comprises:
a first region including an array of a plurality of first perforations, wherein the first region corresponds to a display area of a display panel, and the first perforations are configured for deposition of a deposition material onto corresponding locations on the substrate;
a second region including an array of a plurality of second perforations, wherein the second perforations correspond to a non-display area of the display panel and surround the first region, and the second region is configured as a first deformation absorbing area of the metallic stencil when the metallic stencil is stretched; and
a third region including an array of a plurality of third perforations, wherein the third perforations surround the second region, and the third region is configured as a second deformation absorbing area of the metallic stencil when the metallic stencil is stretched;
wherein the planar section of the shielding plate is disposed below the second region and the third region.

10. The evaporation mask device according to claim 9, wherein the first perforations, the second perforations, and the third perforations are of the same shape and size.

11. The evaporation mask device according to claim 9, wherein rows of the third perforations in the third region are two to three times rows of the second perforations in the second region; and wherein columns of the third perforations in the third region are two to three times columns of the second perforations in the second region.

12. The evaporation mask device according to claim 11, wherein an interval between adjacent rows of the first perforations in the first region, an interval between adjacent rows of the second perforations in the second region, and an interval between adjacent rows of the third perforations in the third region are the same; and wherein an interval between adjacent columns of the first perforations in the first region, an interval between adjacent columns of the second perforations in the second region, and an interval between adjacent columns of the third perforations in the third region are the same.

13. The evaporation mask device according to claim 12, wherein an interval between a row of the first perforations at a periphery of the first region and an adjacent row of the second perforations at a periphery of the second region is identical to the interval between adjacent rows of the first perforations in the first region and identical to the interval between adjacent rows of the second perforations in the second region; and an interval between a column of the first perforations at the periphery of the first region and an adjacent column of the second perforations at the periphery of the second region is identical to the interval between adjacent columns of the first perforations in the first region and identical to the interval between adjacent columns of the second perforations in the second region; and wherein an interval between a row of the third perforations at a periphery of the third region and an adjacent row of the second perforations at the periphery of the second region is identical to the interval between adjacent rows of the third perforations in the third region and identical to the interval between adjacent rows of the second perforations in the second region; and an interval between a column of the third perforations at the periphery of the third region and an adjacent column of the second perforations at the periphery of the second region is identical to the interval between adjacent columns of the third perforations in the third region and identical to the interval between adjacent columns of the second perforations in the second region.
